(19) United States
(12) Patent Application Publication
(10) Pub. No.: US 2010/0039335 A1
(43) Pub. Date: Feb. 18, 2010

(54) APPARATUS AND METHOD FOR MEASURING ANTENNA GAIN USING SUN

(76) Inventors: Jeom-hun LEE, Daejeon-si (KR); Sang-uk LEE, Daejeon-si (KR); Jae-hoon KIM, Daejeon-si (KR); Tae-hee KIM, Daejeon-si (KR)

Correspondence Address: LADAS & PARRY LLP, 224 SOUTH MICHIGAN AVENUE, SUITE 1600, CHICAGO, IL, 60604, US

(21) Appl. No.: 12/504,186

(22) Filed: Jul. 16, 2009

(30) Foreign Application Priority Data
Aug. 13, 2008 (KR) 10-2008-0079622

(51) Int. Cl. G01R 29/08

(52) U.S. Cl. 343/703

(57) ABSTRACT

Provided are an apparatus and method for measuring an antenna gain. The apparatus includes an antenna gain-to-noise-temperature (G/T) ratio calculator for calculating a G/T ratio using a reception noise power measured while an antenna is tracking the sun, a noise temperature measurer for measuring a noise temperature when a signal is transmitted or received through the antenna, and an antenna gain calculator for calculating an antenna gain using the calculated G/T ratio and the measured noise temperature. Thus, it is possible to easily measure the antenna gain of a ground station without a reference antenna or a satellite-mounted device capable of functioning as a reference antenna.

### CROSS REFERENCE TO RELATED APPLICATION

This application claims priority from Korean Patent Application No. 10-2008-0079622, filed on Aug. 13, 2008, the disclosure of which is incorporated herein in its entirety by reference.

### BACKGROUND

1. Field

The present invention relates to an apparatus and method for measuring an antenna gain, and more particularly, to an apparatus and method for measuring an antenna gain of a satellite ground station using the sun.

2. Description of the Related Art

In order to measure an antenna gain of a satellite ground station, a reference antenna transmitting a frequency signal or a satellite signal is needed. In particular, a reference antenna transmitting a transmission frequency signal or a satellite signal is necessary to measure antenna transmission gain. However, since satellite signals are normally received at a ground station antenna, it is impossible to use satellite signals to measure the transmission gain of the ground station antenna.

Thus, to measure an antenna gain of a ground station within a satellite transmission frequency band, a reference antenna having a doughnut-shaped radiation characteristic from the center toward a boresight, i.e., a boresight antenna, is necessary, or else a satellite payload must be used. However, it is difficult to install the reference antenna due to environmental influence, and the satellite payload requires rental cost and time.

### SUMMARY

The present invention provides an apparatus and method for measuring an antenna gain of a satellite ground system without using a reference antenna or a satellite payload.

Additional aspects of the invention will be set forth in the description which follows, and in part will be apparent from the description, or may be learned by practice of the invention.

The present invention discloses an apparatus for measuring an antenna gain including: an antenna gain-to-noise-temperature (G/T) ratio calculator for calculating a G/T ratio using a reception noise power measured while an antenna is tracking the sun; a noise temperature measurer for measuring a noise temperature when a signal is transmitted or received through the antenna; and an antenna gain calculator for calculating an antenna gain using the calculated G/T ratio and the measured noise temperature.

The apparatus may further include a loss measurer for measuring signal loss occurring in a radio frequency (RF) cable for feeding power to the antenna. Here, the antenna gain calculator may additionally reflect the measured signal loss in calculating the antenna gain.

The apparatus may further include: an antenna driver for changing a pointing direction of an antenna reflector; a drive controller for controlling the antenna driver such that the antenna reflector tracks the sun; and a power ratio calculator for measuring the reception noise power while the antenna is tracking the sun and a reception noise power while the antenna is not tracking the sun, and calculating a power ratio on the basis of the measured reception noise powers. Here, the G/T ratio calculator may calculate the G/T ratio using the calculated power ratio.

The present invention also discloses a method of measuring an antenna gain including: measuring a reception noise power while an antenna is tracking the sun; measuring a reception noise power while the antenna is pointinig toward somewhere else in the sky other than the sun; calculating a G/T ratio from the measured reception noise powers; measuring a noise temperature at a specific frequency; and calculating an antenna gain using the calculated G/T ratio and the measured noise temperature.

The method may further include measuring a signal loss between cables. Here, calculating the antenna gain may include additionally reflecting the measured signal loss to calculate the antenna gain.

Calculating the antenna gain may include summing the calculated G/T ratio, the measured noise temperature and the measured signal loss to calculate the antenna gain.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of is the invention and are incorporated in and constitute a part of this specification, illustrate exemplary embodiments of the invention, and together with the description serve to explain the aspects of the invention.

FIG. 1 is a block diagram of an apparatus for measuring an antenna gain according to an exemplary embodiment of the present invention.

FIG. 2 is a flowchart showing a method of measuring an antenna gain according to an exemplary embodiment of the present invention.

### DETAILED DESCRIPTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. Like reference numerals in the drawings denote like elements.

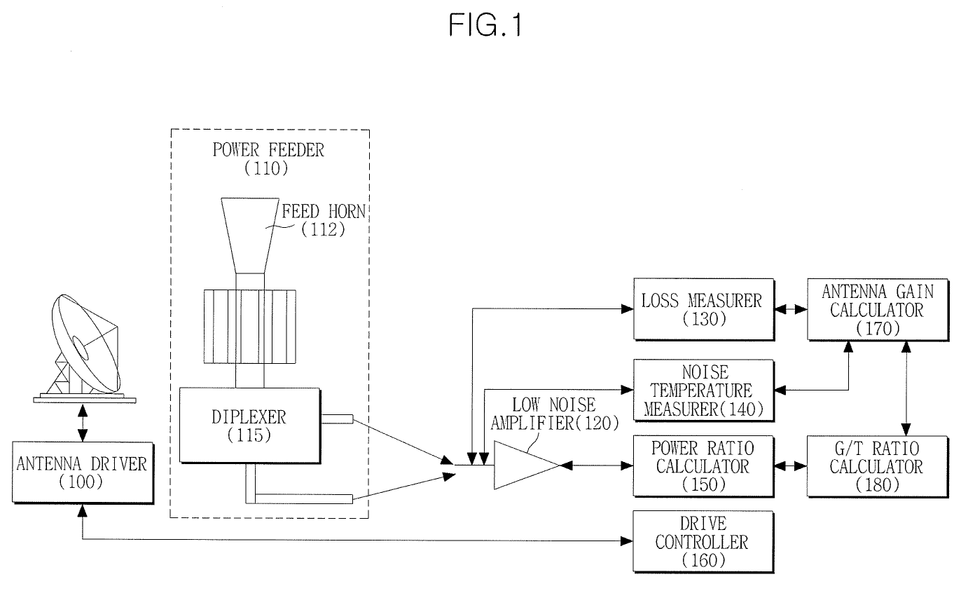

FIG. 1 is a block diagram of an apparatus for measuring an antenna gain according to an exemplary embodiment of the present invention.

As illustrated, the apparatus for measuring an antenna gain according to an exemplary embodiment of the present invention includes an antenna driver 100, a drive controller 160, a power ratio calculator 150, an antenna gain-to-noise-temperature (G/T) ratio calculator 180, a noise temperature measurer 140, a loss measurer 130, and an antenna gain calculator 170.

The antenna driver 100 drives an antenna to change the pointing direction of an antenna reflector. The drive controller 160 controls the antenna driver 100, thereby adjusting the pointing direction of a sun reflector such that the antenna reflector tracks the sun.

The power ratio calculator 150 measures a reception noise power while the antenna reflector is driven by the antenna driver 100 to track the sun, and a reception noise power while the antenna is pointing toward somewhere else in the sky other than the sun. In an exemplary embodiment, a reception noise power can be measured by a power meter such as a spectrum analyzer. Then, a power ratio is calculated on the basis of the measured reception noise powers.

The process of calculating a power ratio using the reception noise power P_{sky} obtained while the antenna is pointing toward somewhere else in the sky other than the sun and the reception noise power Pₛᵤₙ obtained while the antenna is tracking the sun will be described in detail below.

First, the reception noise power P_{sky} obtained while the antenna is pointing toward somewhere else in the sky other than the sun is as follows: P_{sky}=kT_{sys}B.

Here, k denotes Boltzmann's constant (1.38×10⁻²³ watts Hz⁻¹K⁻¹), and T_{sys} denotes system noise temperature including sky noise, ground noise, etc., passing through an antenna sidelobe and backlobe. In other words, the reception noise power P_{sky} includes reception noise powers of all actually generated signals.

And, the reception noise power Pᵤₙ obtained while the antenna is tracking the sun is as follows:

$${P}_{sun} = \frac{G {λ}^{2}}{4 π} Φ B + {kT}_{sys} B .$$

Here, G denotes an antenna gain, λ denotes a signal wavelength, and Φ denotes a light intensity. In other words, the units of the reception noise power Pₛᵤₙ are watts m⁻²Hz⁻¹.

The power ratio calculator 150 calculates a power ratio

$$\frac{{P}_{sun}}{{P}_{sky}}$$

between the measured reception noise powers P_{sky} and Pₛᵤₙ.

The G/T ratio calculator 180 calculates a G/T ratio on the basis of the power ratio calculated by the power ratio calculator 150.

With the power ratio

$$\frac{{P}_{sun}}{{P}_{sky}}$$

set to Y, a G/T ratio is derived from the following equation:

$$\frac{G}{T} = ( \frac{8 π {kL}_{1} {K}_{1}}{{F}_{1} {λ}^{2}} ) ( Y - 1 ) .$$

In the above equation, π is about 3.1415, and k denotes Boltzmann's constant (1.38×10⁻²³ watts Hz⁻¹K⁻¹). L₁ denotes an antenna aperture correction factor of

$$[ 1 + 0.18 {( \frac{Φ d}{Φ h} )}^{2} ] .$$

Here, Φd denotes angle with respect to the sun and is about 0.53, and Φh denotes beam width of a 3 dB electric wave. In addition, K₁ denotes an atmospheric attenuation correction factor of 10(Ag/(10*sin ψ)). Here, Ag (one way zenith) denotes an atmospheric attenuation value varying according to frequency, and ψ denotes antenna elevation angle.

In addition, F₁ denotes a light intensity of a specific frequency and is given by

$${( \frac{{F}_{up}}{{F}_{dn}} )}^{T} {sF}_{dn} .$$

Here, T is equal to

$$\frac{log ( \frac{tf}{{F}_{dn}} )}{log ( \frac{{F}_{up}}{{F}_{dn}} )} .$$

Fᵤₚ denotes a light intensity of a frequency right above the specific frequency, and F_{dn} denotes a light intensity of a frequency right below the specific frequency. Fᵤₚ/F_{dn} can be derived from previously stored information. In an exemplary embodiment, the previously stored information is obtained from the U.S. Dept. of Commerce, the National Oceanic and Atmospheric Administration (NOAA), the Space Weather Prediction Center, and so on.

A power feeder 110 performs power feeding while alternating polarity such that an electric wave is generated from the antenna. The power feeder 110 includes a feed-horn 112 and a diplexer 115. A diplexer is a device that transfers signals separately output from two circuits to one circuit without interference. The diplexer 115 is connected with a low noise amplifier 120 through a transmission power feeder and a reception power feeder.

The low noise amplifier 120 is a radio frequency (RF) amplifier designed to reduce the overall noise figure of a receiver. In this exemplary embodiment, the low noise amplifier 120 is connected with the power feeder 110 through RF cables. The low noise amplifier 120 may be able to normally amplify the corresponding frequency.

The noise temperature measurer 140 measures a system noise temperature T(K) at a specific frequency. Here, the specific frequency is a transmission frequency. The system noise temperature T is measured from a system extending over the RF cables connected with the low noise amplifier 120. In this exemplary embodiment, the system noise temperature T is measured by a hot/cold load measurement method.

The loss measurer 130 measures a loss L(dB) between cables. The loss L between cables is a value corresponding to signal loss occurring in the RF cables between the diplexer 115 and the low noise amplifier 120. Here, the loss measurer 130 measures loss in the separate RF cables. In an exemplary embodiment, the loss measurer 130 may be implemented by a corrected network analyzer. However, the loss measurer 130 is not limited to the corrected network analyzer and may obtain a loss value by receiving an analysis result from a separate network analyzer.

The antenna gain calculator 170 calculates an antenna gain by summing the calculated G/T ratio and the measured system noise temperature and signal loss. In other words, G(dB)=G/T(dB/K)+T(K)+L(dB).

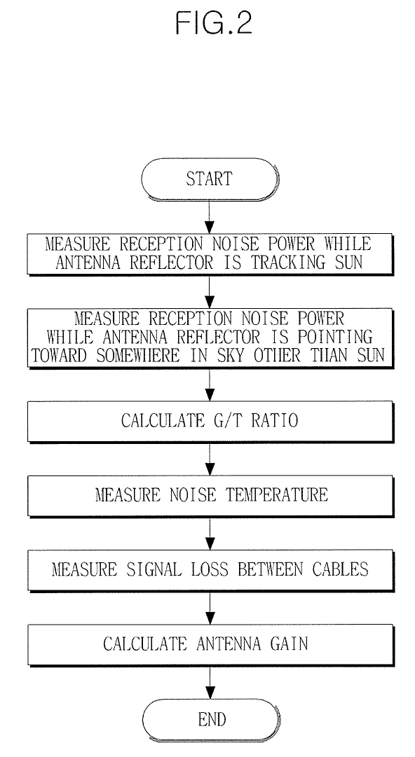

FIG. 2 is a flowchart showing a method of measuring an antenna gain according to an exemplary embodiment of the present invention.

First, a reception noise power is measured while an antenna reflector is pointing toward the sun (S200). The reception noise power Pₛᵤₙ obtained while the antenna reflector is tracking the sun is as follows:

$${P}_{sun} = \frac{G {λ}^{2}}{4 π} Φ B + {kT}_{sys} B .$$

Here, G denotes an antenna gain, λ denotes signal wavelength, and Φ denotes a light intensity. In other words, the units of the reception noise power Pₛᵤₙ are watts m⁻²Hz⁻¹.

And, a reception noise power is measured while the antenna reflector is pointing toward somewhere else in the sky other than the sun (S2 10).

The reception noise power P_{sky} is as follows: P_{sky}=kT_{sys}B. Here, k denotes Boltzmann's constant (1.38×10⁻²³ watts Hz⁻¹K⁻¹), and T_{sys} denotes system noise temperature including sky noise, ground noise, etc., passing through an antenna sidelobe and backlobe. In other words, the reception noise power P_{sky} includes reception noise powers of all actually generated signals.

And, a power ratio

$$\frac{{P}_{sun}}{{P}_{sky}}$$

between the measured reception noise powers P_{sky} and Pₛᵤₙ is calculated.

Subsequently, a G/T ratio is calculated using the power ratio

$$\frac{{P}_{sun}}{{P}_{sky}} ,$$

that is, Y (S220). The G/T ratio may be calculated by the following equation:

$$\frac{G}{T} = ( \frac{8 π {kL}_{1} {K}_{1}}{{F}_{1} {λ}^{2}} ) ( Y - 1 ) .$$

Then, a system noise temperature T(K) is measured at a specific frequency (S230). The system noise temperature T is measured from a system extending over RF cables connected with a low noise amplifier at the specific frequency. In this exemplary embodiment, the system noise temperature T is measured by the hot/cold load measurement method.

In addition, a loss L(dB) between cables is measured (S240). The loss L between cables occurs in the RF cables between a diplexer and the low noise amplifier. Here, loss in the separate RF cables is measured. In an exemplary embodiment, the loss L may be obtained by a network analyzer, and so on.

Subsequently, an antenna gain is calculated by summing the calculated G/T ratio and the measured system noise temperature and signal loss. In other words, G(dB)=G/T(dB/K)+T(K)+L(dB).

According to exemplary embodiments of the present invention, it is possible to easily measure the antenna gain of a ground station without a reference antenna or a satellite-mounted device capable of functioning as a reference antenna.

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. An apparatus for measuring an antenna gain, comprising:
an antenna gain-to-noise-temperature (G/T) ratio calculator for calculating a G/T ratio using a reception noise power measured while an antenna is tracking the sun;
a noise temperature measurer for measuring a noise temperature when a signal is transmitted or received through the antenna; and
an antenna gain calculator for calculating an antenna gain using the calculated G/T ratio and the measured noise temperature.

2. The apparatus of claim 1, further comprising:
a loss measurer for measuring signal loss occurring in a radio frequency (RF) cable for feeding power to the antenna,
wherein the antenna gain calculator additionally reflects the measured signal loss in calculating the antenna gain.

3. The apparatus of claim 1, further comprising:
an antenna driver for changing a pointing direction of an antenna reflector;
a drive controller for controlling the antenna driver such that the antenna reflector tracks the sun; and
a power ratio calculator for measuring the reception noise power while the antenna is tracking the sun and a reception noise power while the antenna is not tracking the sun, and calculating a power ratio on the basis of the measured reception noise powers,
wherein the G/T ratio calculator calculates the G/T ratio using the calculated power ratio.

4. The apparatus of claim 2, further comprising:
a power feeder for performing power feeding while alternating a polarity such that an electric wave is generated from the antenna,
wherein the signal loss occurs in the RF cable connected with the power feeder.

5. The apparatus of claim 4, further comprising:
a low noise amplifier having one end connected with the RF cable connected with the power feeder.

6. The apparatus of claim 1, wherein the G/T calculator calculates the G/T ratio using a light intensity of a specific frequency calculated on the basis of previously stored information.

7. The apparatus of claim 2, wherein the antenna gain calculator calculates the antenna gain by summing the G/T ratio, the signal loss, and the noise temperature.

8. A method of measuring an antenna gain, comprising:
measuring a reception noise power while an antenna is tracking the sun;
measuring a reception noise power while the antenna is pointing toward somewhere in the sky other than the sun;
calculating an antenna gain-to-noise-temperature (G/T) ratio from the measured reception noise powers;
measuring a noise temperature at a specific frequency; and
calculating an antenna gain using the calculated G/T ratio and the measured noise temperature.

9. The method of claim 8, further comprising:
measuring a signal loss between radio frequency (RF) cables,
wherein calculating the antenna gain comprises additionally reflecting the measured signal loss and calculating the antenna gain.

10. The method of claim 9, wherein calculating the antenna gain comprises summing the calculated G/T ratio, the measured noise temperature, and the measured signal loss to calculate the antenna gain.

11. The method of claim 8, wherein calculating the G/T ratio comprises using a light intensity of a specific frequency calculated on the basis of previously stored information to calculate the G/T ratio.
